(19) United States
(12) Patent Application Publication
(10) Pub. No.: US 2025/0151432 A1
(43) Pub. Date: May 8, 2025

(54) OPTICAL ELEMENT WITH DISTANT LAYER

(71) Applicant: VisEra Technologies Company Ltd., Hsin-Chu City (TW)

(72) Inventors: Wen-Yu SHIH, Hsin-Chu City (TW); Chin-Chuan HSIEH, Hsin-Chu City (TW)

(21) Appl. No.: 18/837,748

(22) PCT Filed: Oct. 20, 2022
(86) PCT No.: PCT/CN2022/126413

§ 371 Date: Aug. 12, 2024

(51) Int. Cl. H10F 39/00

(52) U.S. Cl. CPC H10F 39/805; H10F 39/806

(57) ABSTRACT

An optical element including a substrate; a light sensing device disposed in the substrate; a first distant layer disposed above the substrate, wherein a coefficient of thermal expansion of the first distant layer is between 10 ppm/° C. and 300 ppm/° C., and wherein an angle between the sidewall of the first distant layer and a top surface of the substrate is in a range of 10° to 60°; and an inorganic multilayer film covering a top surface and a sidewall of the first distant layer, wherein a coefficient of thermal expansion of the inorganic multilayer film is between 0.5 ppm/° C. and 30 ppm/° C.

### BACKGROUND

### Field of Invention

The present disclosure relates to optical element. More particularly, the present disclosure relates to the optical element with distant layer.

### Description of Related Art

Inorganic multilayer film is widely used in microelectronic devices, such as light sensor, time-of-flight (TOF) detector, spectrometer, or the like. In order to substantially optimize optical performance of the microelectronic device, the inorganic multilayer film can be integrated with polymer layers to form a stack structure. However, incompatible characteristics of the materials in the stack structure may lead to defects, for example, cracking, wrinkle or peeling of the inorganic multilayer film.

### SUMMARY

According to the disclosure, an optical element includes a substrate, a light sensing device disposed in the substrate, a first distant layer disposed above the substrate, and an inorganic multilayer film covering a top surface and a sidewall of the first distant layer. A coefficient of thermal expansion of the first distant layer is between 10 ppm/° C. and 300 ppm/° C. An angle between the sidewall of the first distant layer and a top surface of the substrate is in a range of 10° to 60°. A coefficient of thermal expansion of the inorganic multilayer film is between 0.5 ppm/° C. and 30 ppm/° C.

In some embodiments, the coefficient of thermal expansion of the first distant layer is between 10 ppm/° C. and 65 ppm/° C.

In some embodiments, an elastic modulus of the first distant layer is between 3 Gpa and 75 Gpa under 25° C. to 100° C. and between 1 Gpa and 30 Gpa under 200° C.

In some embodiments, the first distant layer includes at least one material selected from a group consisting of fluorene oligomer, ethoxylated bisphenol A diacrylate, propylene glycol monomethyl ether, and propylene glycol monomethyl ether acetate.

In some embodiments, a thickness of the first distant layer is between 1 μm and 500 μm.

In some embodiments, the inorganic multilayer film includes at least one material layer selected from a group consisting of silicon oxide, silicon nitride, titanium oxide, niobium oxide, and aluminum oxide.

In some embodiments, the inorganic multilayer film further includes at least one metal layer.

In some embodiments, a thickness of the inorganic multilayer film is between 200 nm and 10 μm.

In some embodiments, the first distant layer has a stepped structure, and the stepped structure includes a horizontal surface adjoining a first sidewall portion and a second sidewall portion of the first distant layer.

In some embodiments, the optical elements further includes a second distant layer disposed between the substrate and the first distant layer, in which the coefficient of thermal expansion of the first distant layer is lower than that of the second distant layer.

In some embodiments, an elastic modulus of the first distant layer is higher than that of the second distant layer.

In some embodiments, the first distant layer covers a top surface of the second distant layer, and the sidewall of the first distant layer is coplanar with a sidewall of the second distant layer.

In some embodiments, an angle between the sidewall of the second distant layer and the top surface of the substrate is in a range of 10° to 60°.

In some embodiments, the first distant layer covers a top surface and a sidewall of the second distant layer, and the sidewall of the first distant layer is parallel with the sidewall of the second distant layer.

In some embodiments, the optical element further includes a second distant layer disposed above the substrate adjacent to the first distant layer, in which the inorganic multilayer film further covers a top surface and a sidewall of the second distant layer.

In some embodiments, the second distant layer further includes a connecting portion contacting the sidewall of the first distant layer, and wherein the inorganic multilayer film further covers a top surface of the connecting portion.

In some embodiments, the optical element further includes a grating layer disposed on the top surface of the first distant layer, in which the inorganic multilayer film covers the grating layer.

In some embodiments, the optical element further includes micro lenses disposed on the top surface of the first distant layer, in which the inorganic multilayer film covers the micro lenses.

In some embodiments, a coefficient of thermal expansion of the substrate is between 0.5 ppm/° C. and 300 ppm/° C.

In some embodiments, an elastic modulus of the substrate is between 1 Gpa and 400 Gpa under 25° C.

It is to be understood that both the foregoing general description and the following detailed description are by examples, and are intended to provide further explanation of the disclosure as claimed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an optical element according to one embodiment of the disclosure.

FIGS. 2, 3, 4, 5, 6, 7, 8, and 9 are schematic cross-sectional views of optical elements according to some embodiments of the disclosure.

FIGS. 10A, 10B, and 10C are cross-sectional views of intermediate stages of forming an optical element according to one embodiment of the disclosure.

### DETAILED DESCRIPTION

The following disclosure provides many different embodiments, or examples, for implementing different features of the provided subject matter. Specific examples of components, arrangements, etc., are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides an optical element including a distant layer and an inorganic multilayer film covering the distant layer, in which a coefficient of thermal expansion (CTE) of the distant layer is between 10 ppm/° C. and 300 ppm/° C., and a coefficient of thermal expansion of the inorganic multilayer film is between 0.5 ppm/° C. and 30 ppm/° C. In addition, an angle between a sidewall of the distant layer and a top surface of the substrate is in a range of 10° to 60°. The mechanical characteristics and the structure of the material layers reduce the stress in and between the inorganic multilayer film and the distant layer. This prevents the inorganic multilayer film from structural defects, which improves the reliability of the optical element.

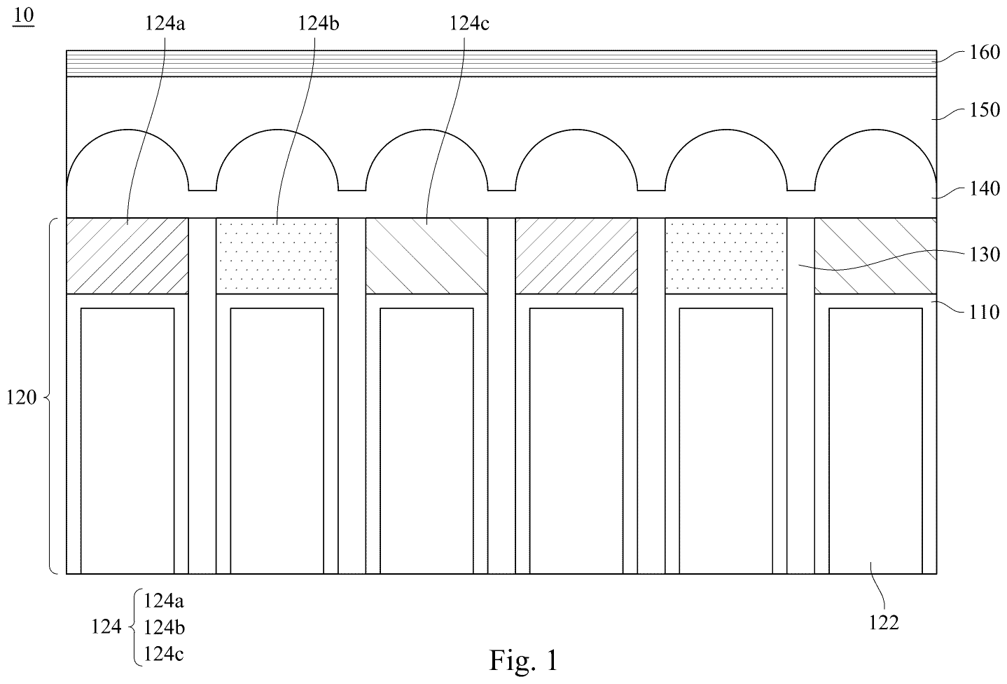

According to one embodiment of the disclosure, FIG. 1 illustrates a cross-sectional view of an optical element 10. The optical element 10 includes a substrate 110, light sensing devices 120, isolation regions 130, micro lenses 140, a distant layer 150, and an inorganic multilayer film 160. Specifically, each of the light sensing devices 120 includes a photodiode 122 and a color filter 124. The photodiode 122 is disposed in the substrate 110, and the color filter 124 is disposed above the corresponding photodiode 122. The light sensing devices 120 may include various types of light sensing sub-devices according to the color filter 124, such as the red light sensing device with a red color filter 124a, the green light sensing device with a green color filter 124b, and the blue light sensing device with a blue color filter 124c shown in FIG. 1.

The light sensing devices 120 are physically separated by isolation regions 130. The isolation regions 130 may prevent the interference between adjacent light sensing devices 120 to provide good resolution of the optical element 10. Although the isolation regions 130 are described/illustrated as being separated from the substrate 110, as used herein, the term “substrate” may refer to the substrate alone or a combination of the substrate and the isolation regions.

The micro lenses 140 are disposed above the light sensing devices 120 to focus the light on the underlying light sensing devices 120. The distant layer 150 is also disposed above the light sensing devices 120 to improve optical quality of the optical element 10, for example, increasing the quantum efficiency (QE) or the resolution of the optical element 10. As shown in FIG. 1, the distant layer 150 is disposed on the micro lenses 140, in which the micro lenses 140 are entirely covered by the distant layer 150. However, in some embodiments, the micro lenses 140 may be alternatively disposed on the distant layer 150.

The inorganic multilayer film 160 is disposed on the distant layer 150 to adjust the light sensing function of the optical element 10. For example, the inorganic multilayer film 160 may be an anti-reflection coating (ARC) layer to increase the transmittance of the light from the light incident surface of the optical element 10 to the light sensing devices 120. For another example, the inorganic multilayer film 160 may be an optical filter for filtering the incident light so that the light sensing devices 120 receive certain wavelength of the light.

When the inorganic multilayer film 160 is formed directly on the distant layer 150, the mechanical properties difference between the inorganic multilayer film 160 and the distant layer 150 may lead to structural defects of the inorganic multilayer film 160, such as crack, peeling or wrinkle. To prevent the inorganic multilayer film 160 from the structural defects after being formed on the distant layer 150, the mechanical characteristics and the structures of the distant layer 150 and the inorganic multilayer film 160 are designed as discussed in greater detail below.

It should be noted that the number and arrangement of components in the optical element 10 shown in FIG. 1 are provided as one or more examples. In practice, there may be additional components, fewer components, different components, or differently arranged components than those shown in FIG. 1.

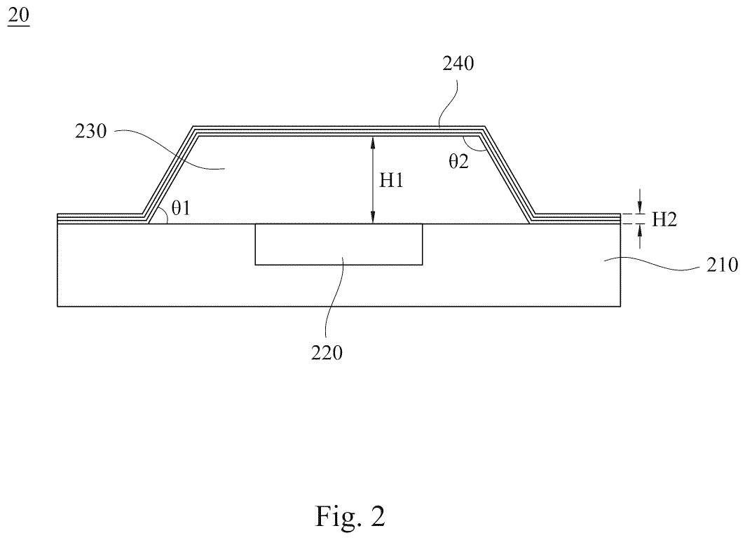

According to one embodiment of the disclosure, FIG. 2 illustrates a schematic cross-sectional view of an optical element 20. The optical element 20 includes a substrate 210, a light sensing device 220 disposed in the substrate 210, a distant layer 230 disposed above the substrate 210, and an inorganic multilayer film 240 on the distant layer 230. The optical element 20 may act as the optical element 10 shown in FIG. 1, although some components, such as additional light sensing devices or micro lenses, of the optical element 20 are not shown in FIG. 2 for illustrative purposes.

Specifically, the distant layer 230 above the substrate 210 covers the light sensing device 220. As such, the incident light goes through the distant layer 230 before reaching the light sensing device 220. In addition, the inorganic multilayer film 240 on the distant layer 230 covers the top surface and the sidewall of the distant layer 230 to form the stack structure. The inorganic multilayer film 240 has low water vapor transmission rate (WVTR) so that external moisture could not easily penetrate into the inorganic multilayer film 240. In other words, the inorganic multilayer film 240 protects the distant layer 230 from the external moisture. Therefore, the distant layer 230 is prevented from absorbing the moisture, which reduces the moisture expansion of the distant layer 230 and the moisture stress in the stack structure of the distant layer 230 and the inorganic multilayer film 240.

More specifically, as shown in FIG. 2, an angle 01 between the sidewall of the distant layer 230 and the top surface of the substrate 210 is in a range of 10° to 60°. The tilted sidewall of the distant layer 230 disperses the stress of the stack structure, which prevents the stress from being concentrated between the sidewall of the distant layer 230 and the substrate 210. This improves the structure stability of the distant layer 230 and the overlying inorganic multilayer film 240 to reduce the structural defects. In some embodiments, an angle θ2 between the sidewall of the distant layer 230 and the top surface of the distant layer 230 may be in a range of 90° to 170° to form the trapezoid stack structure shown in FIG. 2.

Moreover, a coefficient of thermal expansion of the distant layer 230 is between 10 ppm/° C. and 300 ppm/° C., and a coefficient of thermal expansion of the inorganic multilayer film 240 is between 0.5 ppm/° C. and 30 ppm/° C. The distant layer 230 and the inorganic multilayer film 240 with low coefficient of thermal expansion have low thermal stress so that the stack structure may not significantly deformed due to temperature rising in the manufacturing process. As a result, the structural defects in the inorganic multilayer film 240 may be minimized when the inorganic multilayer film 240 is directly formed on the distant layer 230, which improves the performance of the optical element 20.

In some embodiments, the coefficient of thermal expansion of the distant layer 230 and the coefficient of thermal expansion of the inorganic multilayer film 240 may be close enough to minimize the thermal stress between the distant layer 230 and the inorganic multilayer film 240. This prevents the inorganic multilayer film 240 from delamination or peeling. For example, the coefficient of thermal expansion of the distant layer 230 may be between 10 ppm/° C. and 65 ppm/° C. while the coefficient of thermal expansion of the inorganic multilayer film 240 is between 0.5 ppm/° C. and 30 ppm/° C.

In some embodiments, the distant layer 230 may have sufficiently high elastic modulus to prevent the overlying inorganic multilayer film 240 from wrinkle. For example, the elastic modulus of the distant layer 230 may be higher than 3 Gpa under 25° C. to 100° C., such as between 3 Gpa and 75 Gpa under 25° C. to 100° C. If the elastic modulus of the distant layer 230 is lower than 3 Gpa under 25° C. to 100° C., the inorganic multilayer film 240 contacting the distant layer 230 may easily wrinkle. For another example, the elastic modulus of the distant layer 230 may be between 1 Gpa and 30 Gpa under 200° C.

In some embodiments, the distant layer 230 may include suitable polymer material so the intrinsic stress of the distant layer 230 is minimized. For example, the distant layer 230 may include at least one material selected from a group consisting of fluorene oligomer, ethoxylated bisphenol A diacrylate, propylene glycol monomethyl ether, and propylene glycol monomethyl ether acetate. The distant layer 230 including other polymer materials with low intrinsic stress is also contemplated in the disclosure.

In some embodiments, a thickness H1 of the distant layer 230 may be between 1 μm and 500 μm. Specifically, when the thickness H1 of the distant layer 230 is between 1 μm and 50 μm, the incident light may be well focused on the light sensing device 220 below. When the thickness H1 of the distant layer 230 is between 50 μm and 500 μm, the resolution of the optical element 20 may be improved by light beam splitting of the distant layer 230. If the thickness H1 is smaller than 1 μm, the distant layer 230 may not be thick enough to isolate the inorganic multilayer film 240 from the other components below the distant layer 230. If the thickness H1 is larger than 500 μm, the intrinsic stress of the distant layer 230 may be too large, thereby leading to the structural defects in the overlying inorganic multilayer film 240.

In some embodiments, the inorganic multilayer film 240 may include a plurality of thin layers that collectively provide low intrinsic stress (e.g., less than 500 MPa) in the inorganic multilayer film 240. Specifically, the inorganic multilayer film 240 may include at least one material layer selected from a group consisting of silicon oxide (SiOₓ), silicon nitride (SiNₓ), titanium oxide (TiOₓ), niobium oxide (NbₓO_{y}), and aluminum oxide (AlₓO_{y}). For example, the inorganic multilayer film 240 may include a silicon oxide thin layer sandwiched by two silicon nitride thin layers. As silicon oxide provides compressive stress, silicon nitride provides tensile stress to balance the stress in the inorganic multilayer film 240. This reduces the intrinsic stress in the inorganic multilayer film 240. It should be noted that the inorganic multilayer film 240 is illustrated as including three thin layers for illustrative purposes. In some embodiments, the inorganic multilayer film 240 may include any number of the above-mentioned material layer.

In some embodiments, the inorganic multilayer film 240 may optionally include at least one metal layer. For example, the inorganic multilayer film 240 may include gold, silver, copper, aluminum, titanium, combinations thereof, or the like. The metal layer has high absorbance in the long wavelength range so the inorganic multilayer film 240 may absorb the infrared wavelength from the incident light. As a result, the light reaching the light sensing device 220 has a cut band in the infrared wavelength range.

In some embodiments, a thickness H2 of the inorganic multilayer film 240 may be between 200 nm and 10 μm. Specifically, when the total thickness H2 of the thin layers of the inorganic multilayer film 240 is between 200 nm and 10 μm, the incident light may be well optimized to improve the sensitivity and the resolution of the optical element 20. If the thickness H2 is smaller than 200 nm, the inorganic multilayer film 240 may not be thick enough to efficiently stop the external moisture from penetrating. If the thickness H2 is larger than 10 μm, the intrinsic stress of the inorganic multilayer film 240 may be too large, thereby leading to the structural defects in the inorganic multilayer film 240.

In some embodiments, the substrate 210 may be silicon, glass, metal, or polymer substrate having mechanical characteristics compatible with the overlying distant layer 230. For example, a coefficient of thermal expansion of the substrate 210 may be between 0.5 ppm/° C. and 300 ppm/° C. so that the mechanical characteristic of the inorganic multilayer film 240 is compatible with that of the substrate 210. For another example, an elastic modulus of the substrate 210 may be between 1 Gpa and 400 Gpa under 25° C.

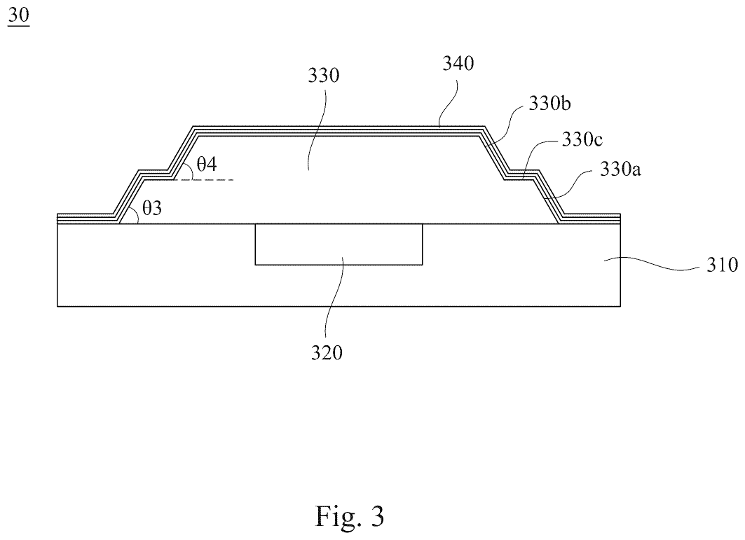

According to some embodiments of the disclosure, FIG. 3 illustrates a schematic cross-sectional view of an optical element 30. The optical element 30 is similar to the optical element 20 in FIG. 2 except for the distant layer.

Specifically, the optical element 30 includes a substrate 310, a light sensing device 320 disposed in the substrate 310, a distant layer 330 disposed above the substrate 310, and an inorganic multilayer film 340 on the distant layer 330.

As shown in FIG. 3, the distant layer 330 has a stepped structure. The stepped structure includes a first sidewall portion 330a, a second sidewall portion 330b, and a horizontal surface 330c adjoining the first sidewall portion 330a and the second sidewall portion 330b. The stepped structure of the distant layer 330 is generally formed by multistep etching process so that the structure parameter bias may be reduced. It should be noted that the distant layer 330 is illustrated as two-stepped structure for illustrative purposes. In some embodiments, the distant layer 330 may have a stepped structure including more than two steps.

More specifically, an angle θ3 between the sidewall of the first sidewall portion 330a and the top surface of the substrate 310 is in a range of 10° to 60°, and an angle θ4 between the sidewall of the second sidewall portion 330b and the horizontal surface 330c is in a range of 10° to 60°. The tilted sidewall portions of the distant layer 330 disperse the stress of the stack structure, which prevents the stress from being concentrated between the first sidewall portion 330a and the substrate 310 or between the second sidewall portion 330b and the horizontal surface 330c.

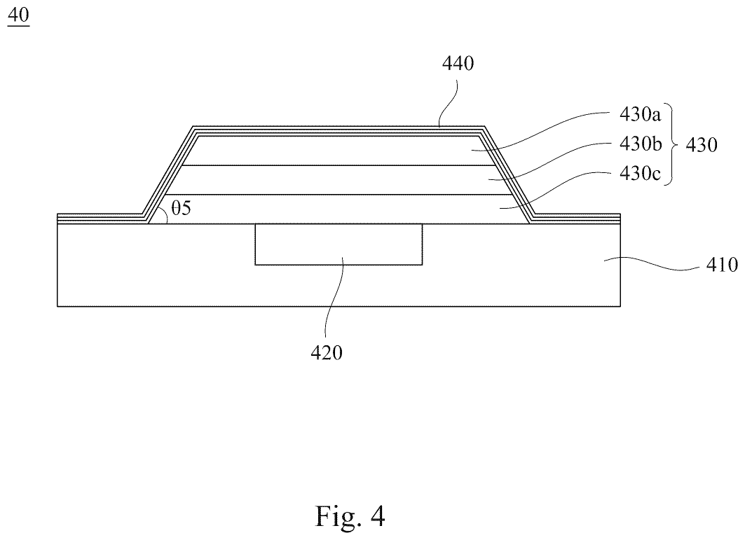

According to some embodiments of the disclosure, FIG. 4 illustrates a schematic cross-sectional view of an optical element 40. The optical element 40 is similar to the optical element 20 in FIG. 2 except for the distant layer. Specifically, the optical element 40 includes a substrate 410, a light sensing device 420 disposed in the substrate 410, a distant layer 430 disposed above the substrate 410, and an inorganic multilayer film 440 on the distant layer 430.

As shown in FIG. 4, the distant layer 430 includes a first distant layer 430a disposed above the substrate 410, a second distant layer 430b disposed between the substrate 410 and the first distant layer 430a, and a third distant layer 430c disposed between the substrate 410 and the second distant layer 430b. The first distant layer 430a covers the top surface of the second distant layer 430b, and the second distant layer 430b covers the top surface of the third distant layer 430c. The sidewall of the first distant layer 430a is coplanar with the sidewalls of the second distant layer 430b and the third distant layer 430c. As a result, the inorganic multilayer film 440 covers the top surface of the first distant layer 430a and the sidewalls of the first distant layer 430a, the second distant layer 430b, and the third distant layer 430c.

More specifically, an angle θ5 between the sidewall of the third distant layer 430c and the top surface of the substrate 410 is in a range of 10° to 60°. The tilted sidewalls of the first distant layer 430a to third distant layer 430c disperse the stress of the stack structure, which prevents the stress from being concentrated between the third distant layer 430c and the substrate 410 or between the three distant layers.

In some embodiments, the coefficient of thermal expansion may decrease upwards in the distant layer 430, so the coefficient of thermal expansion of the topmost sub-layer of the distant layer 430 (for example, first distant layer 430a) is close to that of the inorganic multilayer film 440. As a result, the coefficient of thermal expansion of the first distant layer 430a is lower than that of the second distant layer 430b, and the coefficient of thermal expansion of the second distant layer 430b is lower than that of the third distant layer 430c. In some embodiments, the elastic modulus may increase upwards in the distant layer 430, so the elastic modulus of the first distant layer 430a is close to that of the inorganic multilayer film 440. As a result, the elastic modulus of the first distant layer 430a is higher than that of the second distant layer 430b, and the elastic modulus of the second distant layer 430b is higher than that of the third distant layer 430c. The close mechanical characteristics of the first distant layer 430a and the inorganic multilayer film 440 may minimize the stress between the distant layer 430 and the inorganic multilayer film 440. This prevents the inorganic multilayer film 440 from the structural defects after being formed on the distant layer 430.

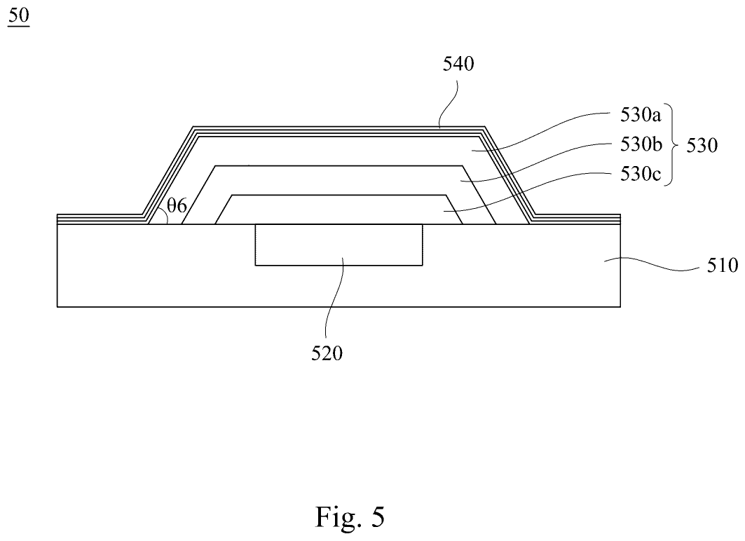

According to some embodiments of the disclosure, FIG. 5 illustrates a schematic cross-sectional view of an optical element 50. The optical element 50 is similar to the optical element 40 in FIG. 4 except for the distant layer. Specifically, the optical element 50 includes a substrate 510, a light sensing device 520 disposed in the substrate 510, a distant layer 530 disposed above the substrate 510, and an inorganic multilayer film 540 on the distant layer 530.

As shown in FIG. 5, the distant layer 530 includes a first distant layer 530a disposed above the substrate 510, a second distant layer 530b disposed between the substrate 510 and the first distant layer 530a, and a third distant layer 530c disposed between the substrate 510 and the second distant layer 530b. The first distant layer 530a covers the top surface and the sidewall of the second distant layer 530b, while the second distant layer 530b covers the top surface and the sidewall of the third distant layer 530c. The sidewall of the first distant layer 530a is parallel with the sidewalls of the second distant layer 530b and the third distant layer 530c. As a result, the inorganic multilayer film 540 covers the top surface and the sidewall of the first distant layer 530a.

More specifically, an angle θ6 between the sidewall of the first distant layer 530a and the top surface of the substrate 510 is in a range of 10° to 60°. Similarly, the angle between the sidewall of the second distant layer 530b and the top surface of the substrate 510 or the angle between the sidewall of the third distant layer 530c and the top surface of the substrate 510 is in a range of 10° to 60°. The tilted sidewalls of the first distant layer 530a to third distant layer 530c disperse the stress of the stack structure, which prevents the stress from being concentrated between the three distant layers and the substrate 510.

In some embodiments, the coefficient of thermal expansion may decrease upwards in the distant layer 530, so the coefficient of thermal expansion of the first distant layer 530a is close to that of the inorganic multilayer film 540. As a result, the coefficient of thermal expansion of the first distant layer 530a is lower than that of the second distant layer 530b, and the coefficient of thermal expansion of the second distant layer 530b is lower than that of the third distant layer 530c. In some embodiments, the elastic modulus may increase upwards in the distant layer 530, so the elastic modulus of the first distant layer 530a is close to that of the inorganic multilayer film 540. As a result, the elastic modulus of the first distant layer 530a is higher than that of the second distant layer 530b, and the elastic modulus of the second distant layer 530b is higher than that of the third distant layer 530c. The close mechanical characteristics of the first distant layer 530a and the inorganic multilayer film 540 may minimize the stress between the distant layer 530 and the inorganic multilayer film 540. This prevents the inorganic multilayer film 540 from the structural defects after being formed on the distant layer 530.

It should be noted that the distant layer 430 and the distant layer 530 are illustrated including three distant sub-layers for illustrative purposes. In some embodiments, the distant layer 430 and the distant layer 530 may include any number of the distant sub-layers, as long as the topmost distant sub-layer has the mechanical characteristics related to the distant layer 230 shown in FIG. 2. For example, a coefficient of thermal expansion of the first distant layer 430a is between 10 ppm/° C. and 300 ppm/° C., so that the inorganic multilayer film 440 formed on the top surface of the first distant layer 430a may be prevented from the structural defects.

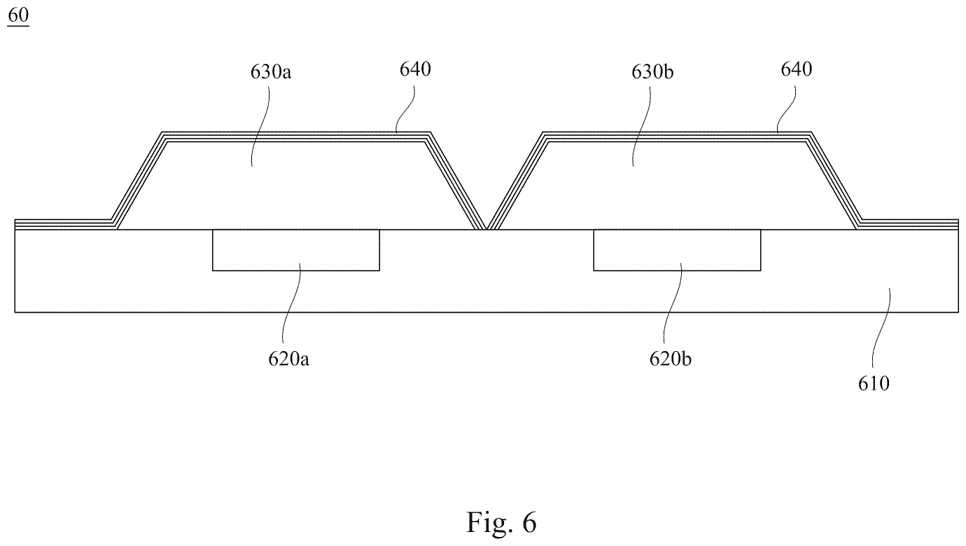

According to some embodiments of the disclosure, FIG. 6 illustrates a schematic cross-sectional view of an optical element 60. The optical element 60 is similar to the optical element 20 in FIG. 2 except for number and arrangement of the distant layer. Specifically, the optical element 60 includes a substrate 610, light sensing devices 620a and 620b disposed in the substrate 610, a first distant layer 630a and a second distant layer 630b disposed above the substrate 610, and an inorganic multilayer film 640 on the first distant layer 630a and the second distant layer 630b.

As shown in FIG. 6, the first distant layer 630a is disposed above the light sensing device 620a to cover the light sensing device 620a. The second distant layer 630b is disposed adjacent to the first distant layer 630a to cover the light sensing device 620b. The first distant layer 630a and the second distant layer 630b are physically separated by a distance on the top surface of the substrate 610. The inorganic multilayer film 640 is continuously formed on the first distant layer 630a and the second distant layer 630b. As such, the inorganic multilayer film 640 not only covers the top surfaces and the sidewalls of the first distant layer 630a and the second distant layer 630b but also covers the top surface of the substrate 610 between the first distant layer 630a and the second distant layer 630b.

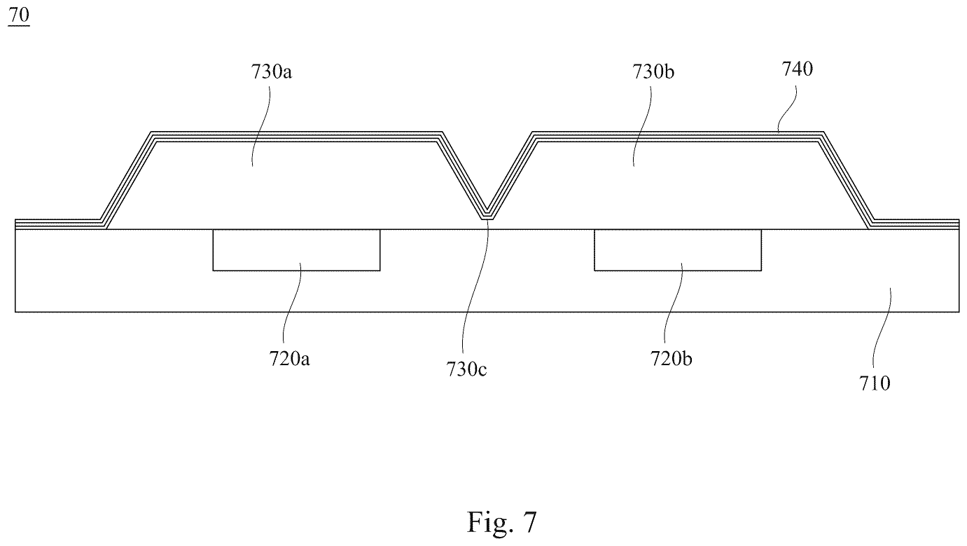

According to some embodiments of the disclosure, FIG. 7 illustrates a schematic cross-sectional view of an optical element 70. The optical element 70 is similar to the optical element 60 in FIG. 6 except for arrangement of the distant layer. Specifically, the optical element 70 includes a substrate 710, light sensing devices 720a and 720b disposed in the substrate 710, a first distant layer 730a and a second distant layer 730b disposed above the substrate 710, and an inorganic multilayer film 740 on the first distant layer 730a and the second distant layer 730b.

Compared to the optical element 60 in FIG. 6, the second distant layer 730b of the optical element 70 further includes a connecting portion 730c extended from the sidewall of the second distant layer 730b. The connecting portion 730c is disposed on the substrate 710 between the first distant layer 730a and the second distant layer 730b. Furthermore, the connecting portion 730c contacts the sidewall of the first distant layer 730a. As shown in FIG. 7, the first distant layer 730a, the second distant layer 730b, and the connecting portion 730c may be integrally formed into one piece so that the three components include the same material. The inorganic multilayer film 740 is continuously formed on the first distant layer 730a, the second distant layer 730b, and the connecting portion 730c. As such, the inorganic multilayer film 740 not only covers the top surfaces and the sidewalls of the first distant layer 730a and the second distant layer 730b but also covers the top surface of the connecting portion 730c.

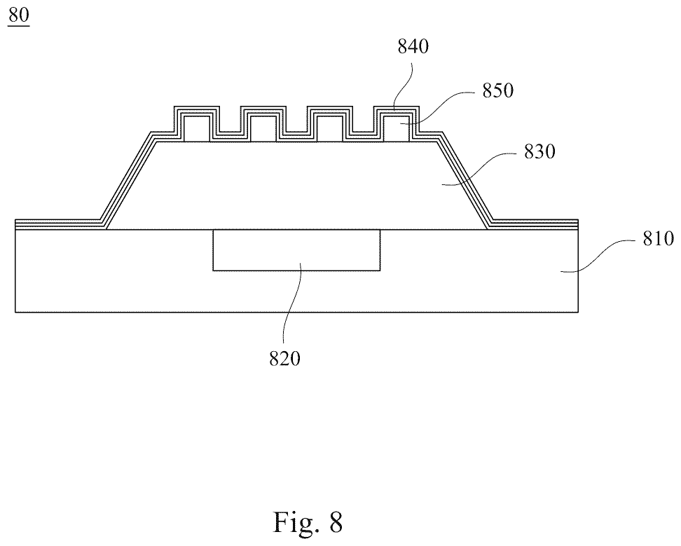

According to some embodiments of the disclosure, FIG. 8 illustrates a schematic cross-sectional view of an optical element 80. The optical element 80 is similar to the optical element 20 in FIG. 2 except for the additional component between the distant layer and the inorganic multilayer film. Specifically, the optical element 80 includes a substrate 810, a light sensing device 820 disposed in the substrate 810, a distant layer 830 disposed above the substrate 810, and an inorganic multilayer film 840 on the distant layer 830.

Compared to the optical element 20 in FIG. 2, the optical element 80 further includes a grating layer 850 disposed on the top surface of the distant layer 830. Specifically, the grating layer 850 includes a plurality of grating structures to spread the incident light into a spectrum to the light sensing device 820 through the distant layer 830. The inorganic multilayer film 840 on the distant layer 830 not only covers the top surface and the sidewall of the distant layer 830 but also covers the grating structures of the grating layer 850. In some embodiments, the grating layer 850 may include a binary grating structure, a step grating structure, a blazed grating structure, or a slanted grating structure.

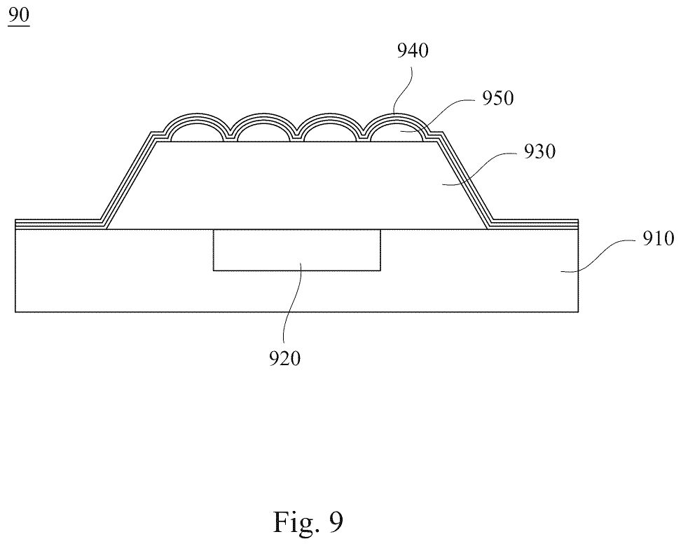

According to some embodiments of the disclosure, FIG. 9 illustrates a schematic cross-sectional view of an optical element 90. The optical element 90 is similar to the optical element 20 in FIG. 2 except for the additional component between the distant layer and the inorganic multilayer film. Specifically, the optical element 90 includes a substrate 910, a light sensing device 920 disposed in the substrate 910, a distant layer 930 disposed above the substrate 910, and an inorganic multilayer film 940 on the distant layer 930.

Compared to the optical element 20 in FIG. 2, the optical element 90 further includes micro lenses 950 disposed on the top surface of the distant layer 930. Specifically, the micro lenses 950 focus the light on the underlying light sensing device 920 to improve the sensitivity of the optical element 90. In some embodiments which the optical element 90 includes a plurality of light sensing devices 920, each of the micro lenses 950 may be aligned right above with the corresponding one of light sensing devices 920. The inorganic multilayer film 940 on the distant layer 930 not only covers the top surface and the sidewall of the distant layer 930 but also covers the micro lenses 950. In some embodiments, each of the micro lenses 950 may include a convex surface or a concave surface.

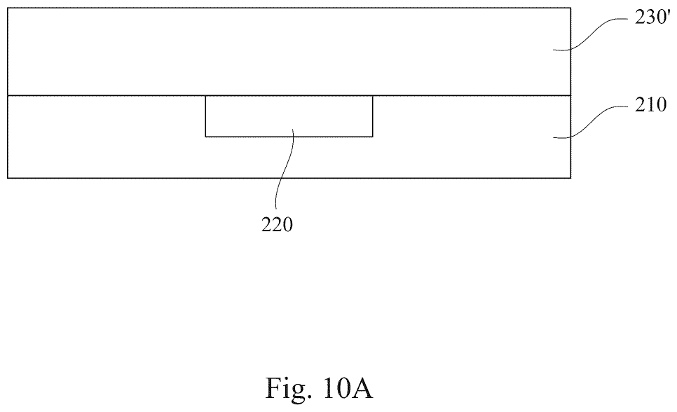

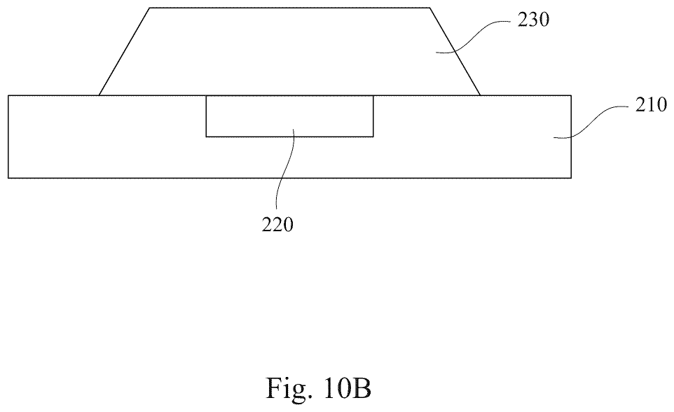

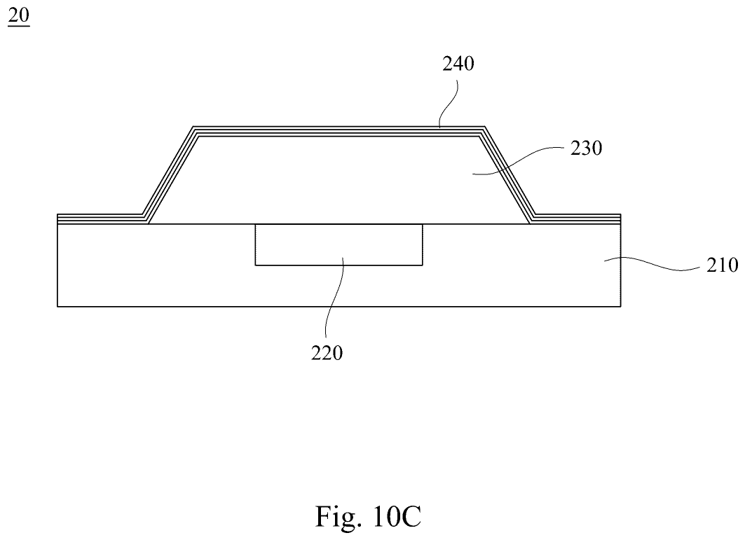

According to one embodiment of the disclosure, FIGS. 10A, 10B, and 10C are cross-sectional views of intermediate stages of the process for forming an optical element with the distant layer below the inorganic multilayer film. For illustrative purposes, the operations illustrated in FIG. 10A to FIG. 10C will be described with reference to the example fabrication process of fabricating the optical element 20 as illustrated in FIG. 2. Operations can be performed in a different order or not performed depending on specific applications. It should be noted that process shown in FIG. 10A to FIG. 10C may not produce a complete optical element. Accordingly, it is understood that additional steps can be provided before, during, and after the illustrated process, and that some other steps may only be briefly described herein.

Referring to FIG. 10A, a blanket distant layer 230′ is formed on a substrate 210. Specifically, the substrate 210 is provided as a carrier substrate with a light sensing device 220 in it. The blanket distant layer 230′ is formed on the top surface of the substrate 210 so that the light sensing device 220 is covered by the blanket distant layer 230′. The blanket distant layer 230′ may be formed by a deposition process, such as spin-coating step followed by baking, or a taping process. In some embodiments, an adhesion layer (not shown) may first be formed on the top surface of the substrate 210. The blanket distant layer 230′ is then formed on the adhesion layer to increase the bonding strength between the blanket distant layer 230′ and the substrate 210.

Referring to FIG. 10B, the blanket distant layer 230′ is patterned to form a distant layer 230. Specifically, a protection layer (not shown), such as a photoresist, is formed on the blanket distant layer 230′. For example, the protection layer may be coated on the blanket distant layer 230′ to cover the top surface of the blanket distant layer 230′. The protection layer is then exposed and developed to form a protection pattern corresponding to the following formed distant layer 230. After the protection pattern is formed, the blanket distant layer 230′ is etched by a wet or dry etching process using the protection pattern as an etching mask. As a result, the blanket distant layer 230′ is patterned into the distant layer 230 with an angle in a range of 10° to 60° between the sidewall of the distant layer 230 and the top surface of the substrate 210.

Referring to FIG. 10C, the inorganic multilayer film 240 is directly deposited onto the distant layer 230 to form the optical element 20. Specifically, the sub-layers of the inorganic multilayer film 240 are sequentially deposited on the distant layer 230 so that the top surface and the sidewall of the distant layer 230 are covered by the inorganic multilayer film 240. For example, the inorganic multilayer film 240 may be deposited by physical vapor deposition (PVD), chemical vapor deposition (CVD), plasma enhanced chemical vapor deposition (PECVD), atomic layer deposition (ALD), plasma enhanced atomic layer deposition (PEALD), or the like. In some embodiments, an adhesion layer (not shown) may first be formed on the top surface of the distant layer 230. The inorganic multilayer film 240 is then formed on the adhesion layer to increase the bonding strength between the inorganic multilayer film 240 and the distant layer 230. In some embodiments, after the inorganic multilayer film 240 is formed on the distant layer 230, the inorganic multilayer film 240 may be further patterned by a lift-off patterning process.

According to the above-mentioned embodiments of the disclosure, the optical element includes the distant layer above the light sensing device and the inorganic multilayer film covering the distant layer. The coefficient of thermal expansion of the distant layer is between 10 ppm/° C. and 300 ppm/° C., and the coefficient of thermal expansion of the inorganic multilayer film is between 0.5ppm/° C. and 30 ppm/° C. As such, the stress in the optical element is reduced, which prevents the inorganic multilayer film from cracking, peeling, or wrinkle on the distant layer and improves the reliability of the optical element. In addition, the angle between the sidewall of the distant layer and the top surface of the substrate is in a range of 10° to 60° so the stress concentration issue can be solved.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optical element, comprising:
a substrate;
a light sensing device disposed in the substrate;
a first distant layer disposed above the substrate, wherein a coefficient of thermal expansion of the first distant layer is between 10 ppm/° C. and 300 ppm/° C., and wherein an angle between a sidewall of the first distant layer and a top surface of the substrate is in a range of 10° to 60°; and
an inorganic multilayer film covering a top surface and the sidewall of the first distant layer, wherein a coefficient of thermal expansion of the inorganic multilayer film is between 0.5 ppm/° C. and 30 ppm/° C.

2. The optical element of claim 1, wherein the coefficient of thermal expansion of the first distant layer is between 10 ppm/° C. and 65 ppm/° C.

3. The optical element of claim 1, wherein an elastic modulus of the first distant layer is between 3 Gpa and 75 Gpa under 25° C. to 100° C. and between 1 Gpa and 30 Gpa under 200° C.

4. The optical element of claim 1, wherein the first distant layer comprises at least one material selected from a group consisting of fluorene oligomer, ethoxylated bisphenol A diacrylate, propylene glycol monomethyl ether, and propylene glycol monomethyl ether acetate.

5. The optical element of claim 1, wherein a thickness of the first distant layer is between 1 μm and 500 μm.

6. The optical element of claim 1, wherein the inorganic multilayer film comprises at least one material layer selected from a group consisting of silicon oxide, silicon nitride, titanium oxide, niobium oxide, and aluminum oxide.

7. The optical element of claim 6, wherein the inorganic multilayer film further comprises at least one metal layer.

8. The optical element of claim 1, wherein a thickness of the inorganic multilayer film is between 200 nm and 10 μm.

9. The optical element of claim 1, wherein the first distant layer has a stepped structure, and wherein the stepped structure comprises a horizontal surface adjoining a first sidewall portion and a second sidewall portion of the first distant layer.

10. The optical element of claim 1, further comprising a second distant layer disposed between the substrate and the first distant layer, wherein the coefficient of thermal expansion of the first distant layer is lower than that of the second distant layer.

11. The optical element of claim 10, wherein an elastic modulus of the first distant layer is higher than that of the second distant layer.

12. The optical element of claim 10, wherein the first distant layer covers a top surface of the second distant layer, and wherein the sidewall of the first distant layer is coplanar with a sidewall of the second distant layer.

13. The optical element of claim 10, wherein an angle between a sidewall of the second distant layer and the top surface of the substrate is in a range of 10° to 60°.

14. The optical element of claim 10, wherein the first distant layer covers a top surface and a sidewall of the second distant layer, and wherein the sidewall of the first distant layer is parallel with the sidewall of the second distant layer.

15. The optical element of claim 1, further comprising a second distant layer disposed above the substrate adjacent to the first distant layer, wherein the inorganic multilayer film further covers a top surface and a sidewall of the second distant layer.

16. The optical element of claim 15, wherein the second distant layer further comprises a connecting portion contacting the sidewall of the first distant layer, and wherein the inorganic multilayer film further covers a top surface of the connecting portion.

17. The optical element of claim 1, further comprising a grating layer disposed on the top surface of the first distant layer, wherein the inorganic multilayer film covers the grating layer.

18. The optical element of claim 1, further comprising micro lenses disposed on the top surface of the first distant layer, wherein the inorganic multilayer film covers the micro lenses.

19. The optical element of claim 1, wherein a coefficient of thermal expansion of the substrate is between 0.5 ppm/° C. and 300 ppm/° C.

20. The optical element of claim 1, wherein an elastic modulus of the substrate is between 1 Gpa and 400 Gpa under 25° C.

17. The optical element of claim 1, further comprising a grating layer disposed on the top surface of the first distant layer, wherein the inorganic multilayer film covers the grating layer.

18. The optical element of claim 1, further comprising micro lenses disposed on the top surface of the first distant layer, wherein the inorganic multilayer film covers the micro lenses.

19. The optical element of claim 1, wherein a coefficient of thermal expansion of the substrate is between 0.5 ppm/° C. and 300 ppm/° C.

20. The optical element of claim 1, wherein an elastic modulus of the substrate is between 1 Gpa and 400 Gpa under 25° C.
